(19) United States
(12) Patent Application Publication
(10) Pub. No.: US 2010/0003035 A1
(43) Pub. Date: Jan. 7, 2010

(54) LASER DIODE HAVING AN ABRUPT TURN-ON, OPTICAL TRANSMITTER DEVICE USING THE SAME LASER DIODE AND OPTICAL COMMUNICATION APPARATUS

(75) Inventors: Sung-Woong Park, Gyeonggi-do (KR); Bong-Kyu Kim, Daejeon-City (KR); Bin-Yeong Yoon, Daejeon-city (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon-city (KR)

(21) Appl. No.: 12/375,437

(22) PCT Filed: Jul. 23, 2007
(86) PCT No.: PCT/KR2007/003546

§ 371 Date: Jan. 28, 2009

(30) Foreign Application Priority Data
Jul. 28, 2006 (KR) 10-2006-0071655

(51) Int. Cl. H04B 10/04; H01S 5/00; H01S 3/0941

(52) U.S. Cl. 398/183; 372/43.01

(57) ABSTRACT

Provided are a laser diode which has low power consumption and can realize a high on/off extinction ratio by small variation of current and which can modulate optical signals at high speed, an optical transmitter, and an optical communication apparatus including the optical transmitter. The laser diode having an abrupt turn-on characteristic, comprises: an active region in which light is generated by application of current and gain is controlled; and an absorption region absorbing light generated in the laser diode at a current lower than an abrupt threshold current that is the same as or lower than an operation current, the operation current being a current level that allows the laser diode to generate a target optical power, wherein the output optical power rapidly increases at the abrupt threshold current.

### CROSS-REFERENCE TO RELATED PATENT APPLICATION

This application claims the benefit of Korean Patent Application No. 10-2006-0071655, filed on Jul. 28, 2006 in the Korean Intellectual Property Office, the disclosure of which is incorporated herein in its entirety by reference.

### BACKGROUND OF THE INVENTION

1. Field of the Invention

The present invention relates to optical communication, and more particularly, to a laser diode used as a light source in optical communication, an optical transmitter comprising the laser diode, and an optical communication apparatus comprising the optical transmitter.

2. Description of the Related Art

A laser device is an optical device that provides highly directional monochromatic light and is widely used in optical communication or optical information processing. Gas lasers and semiconductor lasers are examples of laser devices. Semiconductor laser diodes using a semiconductor are generally used and use semiconductor laser formed at a bonding surface of a p-type semiconductor and an n-type semiconductor by applying a voltage between both ends of a corresponding semiconductor laser diode as a light source.

The above described semiconductor laser diode generates light by applying a current to an active region and then filters the light into light having predetermined wavelengths, and controls the light to have an appropriate gain to output laser light having an appropriate wavelength and power.

FIG. 1 is a graph showing the current-optical power relationship of a conventional semiconductor laser diode.

Referring to FIG. 1, when a current is applied to a conventional semiconductor laser diode, spontaneous emission occurs first at a threshold current Iₜₕ or at a current smaller than the threshold current Iₜₕ outputting no light overall. At a current greater than the threshold current Iₜₕ, enough stimulated emission occurs and the semiconductor laser diode generates enough optical power for laser light to be output.

However, in order to obtain a target optical power PW_{T} required for light sources of optical communication signals, a regular operation current that is greater than the threshold current Iₜₕ should be applied to the semiconductor laser diode. That is, as illustrated in the graph of FIG. 1, the conventional laser diode operates such that optical power increases directly with an increase in current after the threshold current Iₜₕ has been reached, and when the current reaches a regular operation current Iₒₚ, a desired targeted optical power PW_{T} is obtained.

Accordingly, when the desired targeted optical power PW_{T} is very high, the operation current Iₒₚ also is very high, thus requiring high current and great power. Also, when optical signals are modulated on/off, as a spacing between the threshold current Iₜₕ and the operation current Iₒₚ is great, it is difficult to obtain a high on/off extinction ratio by small variation in currents, and thus power consumption is increased. In a direct modulation laser diode, since the current spacing (ΔI₁) between the threshold current Iₜₕ and the operation current Iₒₚ is great, it is difficult to modulate optical signals at high speed, and thus it is difficult to modulate optical signals at high frequency.

Consequently, an optical transmitter or an optical communication apparatus using the conventional laser diode has large power consumption and cannot easily modulate optical signals at high frequency.

### SUMMARY OF THE INVENTION

The present invention provides a laser diode in which power consumption is small and a high on/off extinction ratio can be realized by a small variation of current and optical signals can be modulated at high speed, an optical transmitter comprising the laser diode, and an optical communication apparatus comprising the optical transmitter.

According to an aspect of the present invention, there is provided a laser diode having an abrupt turn-on characteristic, comprising: an active region in which light is generated by application of an electrical current thereto and gain is controlled; and an absorption region absorbing light generated in the laser diode at a current lower than an abrupt threshold current that is the same as or lower than an operation current, the operation current being a current level that allows the laser diode to generate a target optical power, wherein the output optical power rapidly increases at the abrupt threshold current.

The laser diode may absorb the light in the absorption region using an optical device having an absorption function. The optical device may be an absorber, an optical switch, or an optical modulator and may be formed near the active region and in an exit direction in which light of the laser diode is emitted. When the absorption region is formed of an absorber, the absorption region may be formed of an active layer of the active region, and as the absorber absorbs light generated at the threshold current or lower, stimulated emission of the laser diode can be suppressed at the abrupt threshold current or lower.

The abrupt threshold current may be greater than the threshold current, and the same as the operation current or lower than the operation current by a predetermined current. The predetermined current may be 20%, or less than, of the difference between the operation current and the threshold current.

The laser diode may be a direct modulation laser diode which is directly modulated through the current applied to the active region. The laser diode may be directly modulated at high speed by a small variation of current. A high extinction ratio can be realized in the laser diode by a small variation of current. The laser diode may be used as a light source for signal transmission in a burst mode.

The abrupt threshold current may be greater than the threshold current, and the same as the operation current or lower than the operation current by a predetermined current. The predetermined current may be 20%, or less than, of the difference between the operation current and the threshold current.

According to another aspect of the present invention, there is provided an optical transmitter performing optical transmission comprising the laser diode.

According to the present invention, the laser diode can realize the absorption region using an optical device including an absorber, or an optical device switch having an optical power absorption function or an optical modulator.

The laser diode may be a direct modulation laser diode which is directly modulated through the current applied to the active region, and the optical transmitter may be a direct modulation optical transmitter comprising the laser diode. The laser diode may be directly modulated at high speed by a small variation of current and the optical transmitter may be a high speed direct modulation optical transmitter comprising the laser diode.

A high extinction ratio can be realized in the laser diode by a small variation of current. The optical transmitter can operate at low power by including the laser diode. The optical transmitter may transmit signals in a burst mode using the laser diode.

Furthermore, the present invention provides an optical communication apparatus including the optical transmitter to transceive light.

The laser diode having an abrupt turn-on characteristic according to the present invention has a high extinction ratio by small current variation due to the small current spacing between the threshold current and the operation current. Also, the laser diode can operate at low power and directly modulate optical signals at high speed. Also, the optical transmitter or the optical communication apparatus according to the present invention uses a laser diode having an abrupt turn-on characteristic as a light source for direct modulation, thereby reducing the costs for high speed modulation, and since low power signals are used, an economical optical communication system can be realized in consideration of costs of signal operation.

### BRIEF DESCRIPTION OF THE DRAWINGS

The above and other features and advantages of the present invention will become more apparent by describing in detail exemplary embodiments thereof with reference to the attached drawings in which:

FIG. 1 is a graph showing the current-optical power characteristic of a conventional semiconductor laser diode;

FIG. 2 is a graph showing the current-optical power characteristic of a laser diode having an abrupt turn-on characteristic according to an embodiment of the present invention;

FIG. 3 is a graph showing the principle of the laser diode having an abrupt turn-on characteristic according to an embodiment of the present invention; and

FIG. 4 is a cross-sectional view of a laser diode having an abrupt turn-on characteristic according to the present invention.

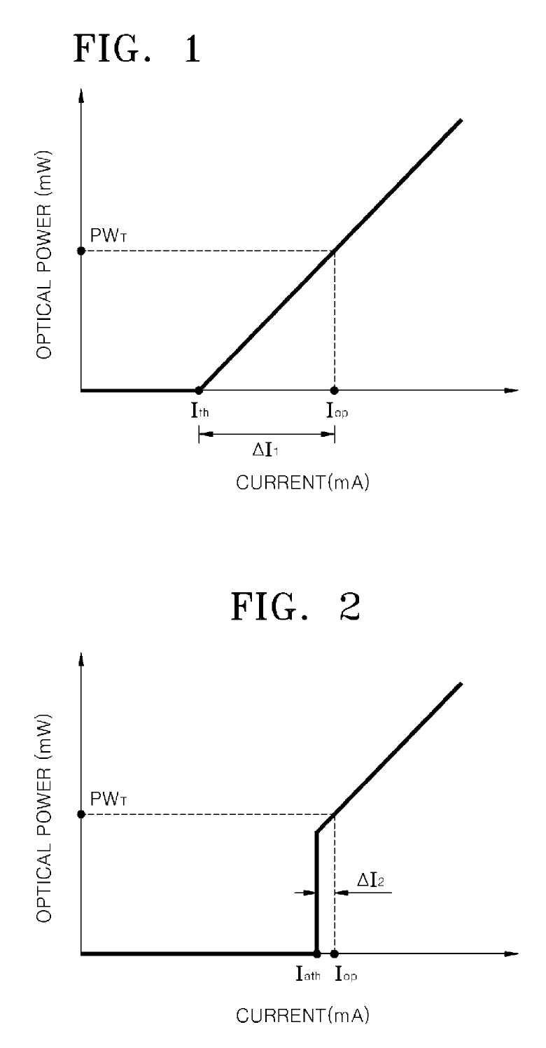

### DETAILED DESCRIPTION OF THE INVENTION

The present invention will now be described more fully with reference to the accompanying drawings, in which exemplary embodiments of the invention are shown.

The present invention will now be described more fully with reference to the accompanying drawings, in which exemplary embodiments of the invention are shown. It will be understood that when a layer is referred to as being “on” another layer or substrate, it can be directly on the other layer or substrate, or intervening layers may also be present. Also, in the drawings, the thicknesses of layers and regions are exaggerated for clarity. Like reference numerals in the drawings denote like elements, and thus their description will be omitted. The terms used are for illustrative purpose of the present application only and are not intended to limit the scope of the significance or the scope of the present invention described in the claims.

FIG. 2 is a graph showing the current-optical power relationship of a laser diode having an abrupt turn-on characteristic according to an embodiment of the present invention.

Referring to FIG. 2, the optical power of the laser diode increases rapidly at an abrupt threshold current Iₐₜₕ. The abrupt threshold current Iₐₜₕ is greater than a threshold current Iₜₕ. The abrupt threshold current Iₐₜₕ can be achieved by changing the structure and the material of the laser diode. More will be described about the abrupt threshold current Iₐₜₕ with reference to FIG. 4.

The abrupt threshold current Iₐₜₕ may be greater than the threshold current Iₜₕ and may be almost as great as an operation current Iₒₚ or may be slightly lower than the operation current Iₒₚ. For example, the abrupt threshold current Iₐₜₕ may be lower than the operation current Iₒₚ by 20% or less of the difference between the abrupt threshold current Iₐₜₕ and the threshold current Iₜₕ.

As the optical power of the laser diode increases rapidly at the abrupt threshold current Iₐₜₕ and then increases in proportion with the applied current above the abrupt threshold current Iₐₜₕ, a desired targeted optical power PW_{T} can be achieved by a small increase of current after turn-on of the laser diode. When the abrupt threshold current Iₐₜₕ is the same or nearly the same as the operation current Iₒₚ, the turn-on of the laser diode and the obtaining of the targeted optical power PW_{T} can occur at the same time or after only a short delay.

Accordingly, since the current spacing ΔI₂ between the abrupt threshold current Iₐₜₕ and the operation current Iₒₚ is small, high on/off extinction ratio can be achieved by a small variation of current. Also, when the laser diode is directly modulated, direct modulation at high frequency is possible based on the high extinction ratio. Also, the power consumption can be significantly reduced based on the abrupt threshold current Iₐₜₕ during frequency modulation. In other words, the laser diode according to the present invention can output sufficient optical power with low power RF operation.

More will be described about modulation in detail. The output optical signals are modulated by direct modulation or external modulation. Direct modulation refers to modulating the output of the laser diode by directly switching a current to the laser diode on and off. External modulation refers to modulating the output of the laser diode output in continuous waves using an external optical modulator such as an optical device switch. In general, direct modulation is economical from the aspect of manufacturing a laser diode; however, when the difference between the threshold current Iₜₕ and the operation current Iₒₚ is great, high speed modulation is difficult. That is, in the case of direct modulation, optical oscillation is disturbed by modulation and thus deteriorates.

External modulation is performed while maintaining the laser oscillation state, and is less economical because an additional external optical modulator needs to be attached to the laser, and as such the manufacturing process thereof is more complicated than direct modulation. Also, the manufacturing cost of the external optical modulator is high since generally an external optical modulator is manufactured of LiNbO₃, polymer etc. having nonlinear optical characteristics.

The laser diode according to an embodiment of the present invention can maintain a minute current spacing ΔI₂ between the abrupt threshold current Iₐₜₕ and the operation current Iₒₚ, and accordingly, high speed direct modulation can be performed. Accordingly, the price of the laser diode or the optical transmitter or the optical communication apparatus including the laser diode can be reduced, thereby realizing a very economical optical communication system.

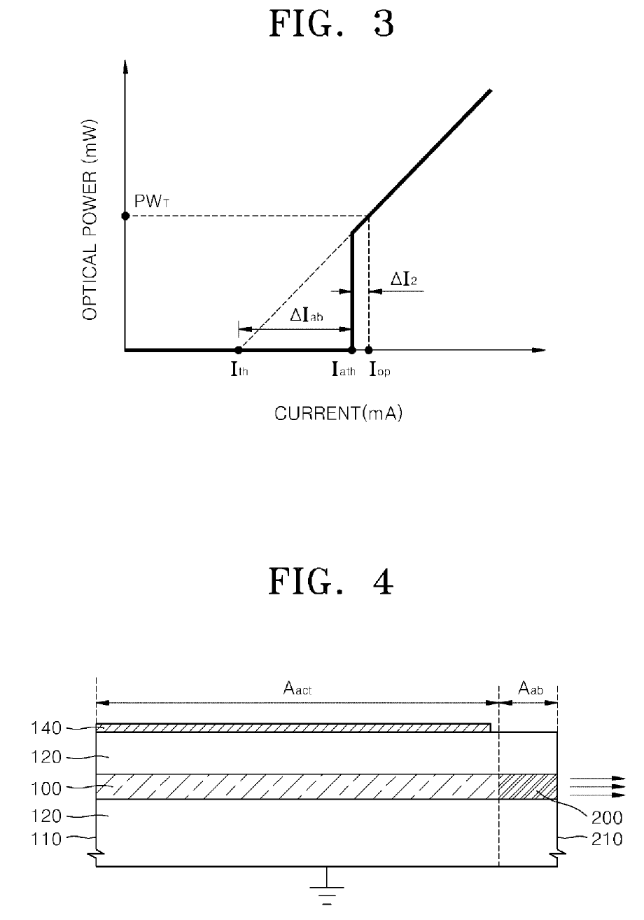

FIG. 3 is a graph for illustrating the principle of the laser diode having an abrupt turn-on characteristic according to an embodiment of the present invention.

Referring to FIG. 3, the laser diode according to the present invention suppresses stimulated emission in a spacing ΔI_{ab} between the threshold current Iₜₕ and the abrupt threshold current Iₐₜₕ, also referred to as an extinction state. In other words, light generated in the active region is absorbed in a region when the applied current is between the threshold current Iₜₕ and the abrupt threshold current Iₐₜₕ or light emission is suppressed in other ways. Accordingly, the laser diode maintains the extinction state until the abrupt threshold current Iₐₜₕ and the laser diode is turned on at the abrupt threshold current Iₐₜₕ. Consequently, optical power is output at the abrupt threshold current Iₐₜₕ and increases abruptly. Since the current spacing ΔI₂ between the operation current Iₒₚ and the abrupt threshold current Iₐₜₕ is small, the target optical power PW_{T} can be easily output by a small increase of the current at the abrupt threshold current Iₐₜₕ.

The above described light absorption or suppression of stimulated emission can be realized by inserting an absorber in the active region of the laser diode or by combining an optical device such as an optical device switch or an optical modulator having a optical power absorption function to a laser diode.

FIG. 4 is a cross-sectional view of a laser diode having an abrupt turn-on characteristic according to the present invention.

Referring to FIG. 4, the laser diode according to an embodiment of the present invention includes an active region A_{act} in which laser light is generated by application of a current; and an absorption region A_{ab} absorbing light that is generated at currents ranging from a threshold current to at a predetermined current that is greater than the threshold current.

The active region A_{act} includes a core or an active layer 100, a clad 120 disposed on and under the active layer 100, and an active region electrode 140 for applying current to the active region. The active layer 100 can be formed of a semiconductor material such as indium gallium arsenide phosphate (InGaAsP) or aluminum gallium arsenide (AlGaAs) as a bulk or in a multi-quantum well structure. The clad 120 is disposed on and under the active layer 100, and can be formed as a p type and n type indium phosphate (InP). The active region electrode 140 is formed of a conductive material and is usually a metal electrode.

When current is applied to the active region A_{act}, stimulated emission occurs as described above, and light by the stimulated emission may be emitted through an exit surface 210 of the laser diode. In general, the exit surface 210 of the laser diode is anti-reflection (AR) coated, and a rear surface 110, that is, the opposite surface of the exit surface 210 is high reflection (HR) coated.

The absorption region A_{ab} has a similar structure as the active region A_{act}. However, unlike the active region A_{act}, in the absorption region A_{ab} an absorber 200 absorbing light is formed instead of the active layer 100. The absorber 200 is influenced by the current applied to the active region A_{act} to absorb light at currents that are as great as the abrupt threshold current Iₐₜₕ or lower than the abrupt threshold current Iₐₜₕ, and to transmit light at currents greater than the abrupt threshold current Iₐₜₕ, thereby realizing a laser diode having an abrupt turn-on characteristic. Meanwhile, the absorber 200 can be formed of the same material as that of the active layer 100 of the active region A_{act}, and accordingly, the laser diode of the present invention can be realized using a conventional laser diode structure.

An absorber 200 is used in the current embodiment of the present invention to absorb the light emitted by stimulated emission at currents that are the same as or lower than the abrupt threshold current Iₐₜₕ, however, an optical device such as an optical device switch or an optical modulator which can absorb light or suppress stimulated emission can be attached to the laser diode to obtain the same effect. Also, the absorption region A_{ab} is formed beside the exit surface 210 of the laser diode, however, the absorption region A_{ab} can also be formed at other portions of the laser diode.

An optical transmitter that is low-priced and can be directly modulated at high speed can be realized using the laser diode of the present invention, and accordingly, an economical optical communication device or an optical communication system including an optical transmitter can be realized.

As described above, the laser diode according to the present invention includes an absorption region and thus can have an abrupt turn-on characteristic in which optical power rapidly increases at an abrupt threshold current. Accordingly, a high on/off extinction ratio due to a small current variation between the abrupt threshold current and an operation current Iₒₚ can be obtained, and high frequency direct modulation is possible.

Also, the laser diode according to the present invention can have sufficient optical output while using the high on/off extinction ratio which can be realized by a small variation of current and can operate at low power radio frequencies (RF).

Furthermore, the laser diode can be used as a light source in the present invention, and thus an optical transmitter or an optical communication apparatus including the optical transmitter can be realized economically.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A laser diode having an abrupt turn-on characteristic, comprising:
an active region in which light is generated by application of an electrical current thereto and gain is controlled; and
an absorption region absorbing light generated in the laser diode at a current lower than an abrupt threshold current that is the same as or lower than an operation current, the operation current being a current level that allows the laser diode to generate a target optical power,
wherein the output optical power rapidly increases at the abrupt threshold current.

2. The laser diode of claim 1, wherein the laser diode absorbs the light in the absorption region using an optical device having an absorption function.

3. The laser diode of claim 2, wherein the optical device is disposed adjacent to the active region and in the direction of an exit surface in which light of the laser diode is output.

4. The laser diode of claim 2, wherein the optical device is an absorber, an optical switch, or an optical modulator.

5. The laser diode of claim 1, wherein the abrupt threshold current is greater than the threshold current, and is the same as the operation current or lower than the operation current by a predetermined current.

6. The laser diode of claim 5, wherein the predetermined current is 20%, or less than, of the difference between the operation current and the threshold current.

7. The laser diode of claim 1, wherein the laser diode is a direct modulation laser diode which is directly modulated through the current applied to the active region.

8. The laser diode of claim 1, wherein the laser diode can be directly modulated at high speed by a small variation of current.

9. The laser diode of claim 1, wherein a high extinction ratio can be realized in the laser diode by a small variation of current.

10. The laser diode of claim 1, wherein the laser diode is used as a light source for signal transmission in a burst mode.

11. An optical transmitter performing optical transmission comprising the laser diode of claim 1.

12. The optical transmitter of claim 11, wherein the laser diode absorbs light in the absorption region thereof using an optical device absorbing light.

13. The optical transmitter of claim 12, wherein the optical device is an absorber, an optical switch or an optical modulator.

14. The optical transmitter of claim 11, wherein the laser diode is a direct modulation laser diode which is directly modulated through the current applied to the active region, and the optical transmitter is a direct modulation optical transmitter comprising the laser diode.

15. The optical transmitter of claim 11, wherein the laser diode can be directly modulated at high speed by a small variation of current and the optical transmitter is a high speed direct modulation optical transmitter comprising the laser diode.

16. The optical transmitter of claim 11, wherein the optical transmitter transmits signals in a burst mode using the laser diode.

17. An optical communication apparatus comprising the optical transmitter of claim 11 and transceiving light.
